(19) United States
(12) Patent Application Publication
(10) Pub. No.: US 2025/0031324 A1
(43) Pub. Date: Jan. 23, 2025

(54) ELECTRONIC KEY ACCOMMODATION CASE AND ELECTRONIC KEY OPERATION DEVICE

(71) Applicant: YOKOWO CO., LTD., Chiyoda-ku, Tokyo (JP)

(72) Inventor: Tsugio YAMAMOTO, Tokyo (JP)

(73) Assignee: YOKOWO CO., LTD., Chiyoda-ku, Tokyo (JP)

(21) Appl. No.: 18/714,424

(22) PCT Filed: Sep. 27, 2022
(86) PCT No.: PCT/JP2022/035878

§ 371 Date: May 30, 2024

(30) Foreign Application Priority Data
Nov. 30, 2021 (JP) 2021-195017

(51) Int. Cl. H05K 5/02; B60R 25/24

(52) U.S. Cl. CPC H05K 5/0217; B60R 25/24

(57) ABSTRACT

An electronic key accommodation case that is detachably attached to an electronic key operation device configured to press a pressing button of an accommodated electronic key. The electronic key accommodation case includes: a housing configured to accommodate the electronic key; and a position regulating unit configured to regulate a position of the electronic key in the housing. The housing includes a plurality of positioning units that position the position regulating unit.

### TECHNICAL FIELD

The present invention relates to an electronic key accommodation case and an electronic key operation device, and more particularly, to an electronic key accommodation case and an electronic key operation device used in an electronic key operation device for operating an accommodated electronic key from outside.

### BACKGROUND ART

For example, as usage forms of an automobile, there is a form in which a plurality of persons share one or a plurality of vehicles. This corresponds to car sharing and rental cars. Hereinafter, such usage forms are collectively referred to as “sharing”.

In sharing, handling of a key for using a vehicle to be shared is important. For example, Patent Literature 1 discloses a storage case of an electronic key for receiving and delivering an electronic key in an unattended manner in sharing. In the invention of Patent Literature 1, communication is performed from outside the vehicle using a smartphone or the like with a storage case in the vehicle in which an electronic key is stored. Further, when a button of the electronic key in the vehicle is operated from outside the vehicle, a door lock of an automobile is unlocked and the electronic key in the vehicle can be received.

### CITATION LIST

### Patent Literature

Patent Literature 1: WO 2021/054404

### SUMMARY OF INVENTION

### Technical Problem

In the storage case of the electronic key described in Patent Literature 1, it is necessary to change an arrangement of a pressing portion that presses the button or a shape of a storage space of the electronic key according to the button and an outer shape of the electronic key. Therefore, it is necessary to design and manufacture the storage cases according to various electronic keys existing in the world. On the other hand, it is also conceivable to embed the electronic key by forming a holding unit with a material having flexibility so that a thickness changes according to the outer shape of the electronic key so as to correspond to the various electronic keys. However, in this case, for example, when a strong force is applied at the time of pressing the button, the holding unit is deformed, or in the case of a high temperature, the flexibility of the holding unit is too high, and thus the holding unit is deformed. There is a chance that fluctuation or positional deviation of the electronic key occurs, and reliability of a pressing operation over a long period may be difficult to secure.

Accordingly, an object of the invention is to provide an electronic key accommodation case and an electronic key operation device corresponding to various electronic keys while securing reliability of a pressing operation.

### Solution to Problem

According to one aspect of the invention, provided is an electronic key accommodation case that is detachably attached to an electronic key operation device configured to press a pressing button of an accommodated electronic key, the electronic key accommodation case includes: a housing configured to accommodate the electronic key; and a position regulating unit configured to regulate a position of the electronic key in the housing. The housing includes a plurality of positioning units that position the position regulating unit.

In the electronic key accommodation case according to such an aspect, since the position regulating unit is selectively attached to any one of the plurality of positioning units, the electronic key can be positioned and held in the housing by making the arrangement of the position regulating unit correspond to the shape of the electronic key. Accordingly, it is possible to cope with various electronic keys while securing reliability of the pressing operation on the electronic key.

In one aspect of the invention, the position regulating unit regulates a movement of the electronic key with respect to the housing in a height direction and a horizontal direction intersecting the height direction.

In one aspect of the invention, the position regulating unit is divided into a plurality of partial regulating units, and each of the partial regulating units is independently positioned at any one of the plurality of positioning units.

In one aspect of the invention, the position regulating unit includes a holding unit that is in contact with and holds the electronic key, and the holding unit and the positioning unit overlap each other in a plan view.

In one aspect of the invention, the position regulating unit includes a tapered portion inclined with respect to a bottom surface of the housing.

In one aspect of the invention, the positioning unit is unevenness provided on a bottom surface of the housing, has a rack gear shape in which a plurality of the unevenness are arranged in a line, and an engaging portion that engages with the unevenness is provided on a surface of the position regulating unit facing the bottom surface.

In one aspect of the invention, the position regulating unit includes an extension portion extending to a side surface of the housing, and the extension portion is in contact with the side surface.

In one aspect of the invention, a plurality of indicator units configured to distinguish the plurality of positioning units are provided in the housing, and in a state in which the position regulating unit is selectively attached to the positioning unit, at least one of the indicator units is provided at a position not overlapping the position regulating unit.

In addition, in one aspect of the invention, an electronic key operation device that presses a pressing button of an accommodated electronic key includes: an electronic key accommodation case configured to accommodate the electronic key; and a pressing member configured to press the button of the electronic key accommodated in the electronic key accommodation case. The electronic key accommodation case includes a housing configured to accommodate the electronic key, a position regulating unit configured to regulate a position of the electronic key in the housing, and a plurality of positioning units configured to position the position regulating unit.

### Advantageous Effects of Invention

According to an aspect of the invention, it is possible to provide an electronic key accommodation case and an electronic key operation device corresponding to various electronic keys while securing reliability of a pressing operation.

### BRIEF DESCRIPTION OF DRAWINGS

FIG. 1 is a schematic diagram showing a system configuration example of a sharing system using an electronic key accommodation case 300 according to the invention.

FIG. 2 conceptually shows an operation of an electronic key operation device 100 according to an embodiment.

FIGS. 3A to 3C show schematic diagrams showing an outline of the electronic key accommodation case 300 according to a first embodiment, where FIG. 3A is an exploded perspective view, FIG. 3B is a perspective view showing an assembly state in which a lid 50 is opened, and FIG. 3C is a perspective view showing an assembly state in which the lid 50 is closed.

FIG. 4 is a schematic cross-sectional view of an electronic key 200 along a longitudinal direction, showing the outline of the electronic key accommodation case 300.

FIGS. 5A and 5B show schematic diagrams showing a structure of a position regulating unit 20 according to the first embodiment, where FIG. 5A is an upper perspective view, and FIG. 5B is a lower perspective view.

FIGS. 6A and 6B show schematic diagrams showing an arrangement of the position regulating unit 20 inside a housing 10, where FIG. 6A is a top view, and FIG. 6B is a perspective view.

FIG. 7 is a schematic cross-sectional view of the electronic key 200 along a transverse direction, showing the outline of the electronic key accommodation case 300.

FIGS. 8A and 8B show schematic diagrams showing holding of the electronic keys 200 having different forms by the position regulating unit 20, where FIG. 8A shows a case in which a cross section is close to a rectangle and has corners, and FIG. 8B shows a case in which the cross section is close to an ellipse or an oval and has no corner.

FIG. 9 is a schematic perspective view showing a structure of a position regulating unit 120 according to a second embodiment.

### DESCRIPTION OF EMBODIMENTS

### First Embodiment

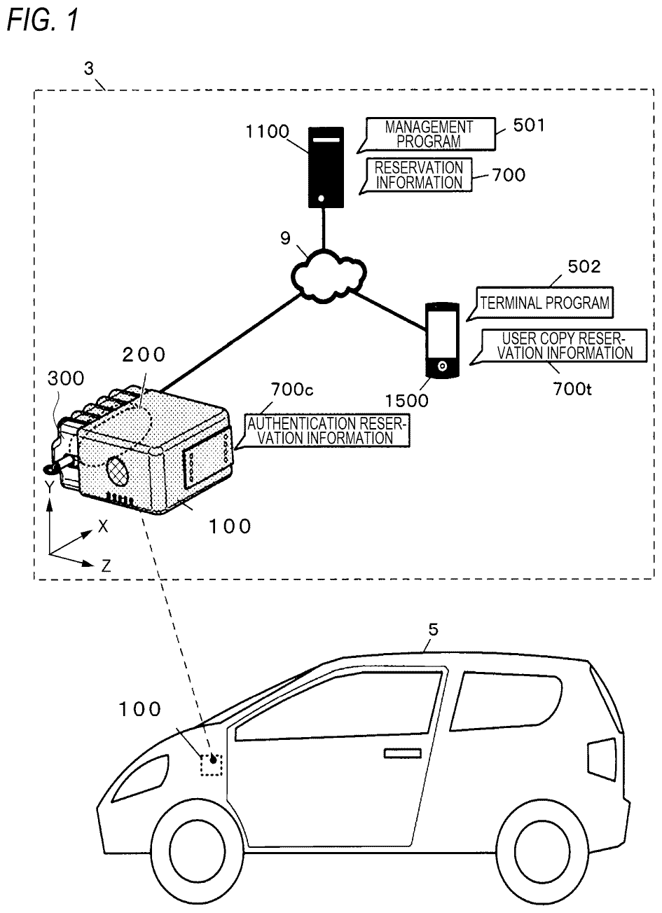

Hereinafter, embodiments of the invention will be described in detail with reference to the drawings. The same or equivalent components, members, and processes shown in the drawings are denoted by the same reference numerals, and redundant description thereof will be omitted as appropriate. In a cross-sectional view, a cross section of each member is represented by various oblique lines for easy discrimination from other members, but a difference in oblique lines does not represent the difference in material, shape, or the like of the member. Also in the perspective view, each member is represented by a color or a dot in order to be easily distinguished from other members, but this difference does not represent a difference in material, shape, or the like of the member. FIG. 1 is a schematic diagram showing a system configuration example of a sharing system using the electronic key accommodation case 300 according to the invention.

A sharing system 3 includes a vehicle 5 to be shared, the electronic key accommodation case 300 that accommodates the genuine electronic key 200 attached to the vehicle 5, an electronic key operation device 100 that is an in-vehicle device to which the electronic key accommodation case 300 is attached, a server system 1100 that performs communication connection with the electronic key operation device 100 via a network 9, and a user terminal 1500 used by a user to be shared who performs communication connection with the electronic key operation device 100 via the network 9. The vehicle 5 is equipped with at least one electronic key operation device 100. When the sharing system 3 is actually operated, one or a plurality of sets of the vehicle 5 and the electronic key operation device 100 are prepared, and one or a plurality of user terminals 1500 corresponding to the one or the plurality of prepared sets are used.

The electronic key 200 includes an unlocking button and a locking button which are pressing buttons for unlocking or locking a locking mechanism provided in the vehicle 5 to be shared. The electronic key 200 transmits a predetermined unlocking signal when the unlocking button is pressed, and transmits a predetermined locking signal when the locking button is pressed. The network 9 means a communication path through which data communication is possible. A communication method may be wired or wireless. The electronic key accommodation case 300 is a member that accommodates the electronic key 200 therein, is mounted on the electronic key operation device 100, and holds the electronic key 200 so that the unlocking button or the locking button can be pressed down by driving the electronic key operation device 100.

The server system 1100 performs user registration of the sharing system 3, reservation management, and provision of reservation information to the user terminal 1500 and the electronic key operation device 100. Specifically, by storing and executing a management program 501, the server system 1100 implements (1) a user registration function, (2) a reservation setting function for each vehicle 5, (3) a function of generating reservation information 700 (for example, including a unique reservation ID, a reserved vehicle ID, a reservation period, and a password), (4) a function of providing a copy of the reservation information 700 (reservation information 700t) to the user terminal 1500, and (5) a function of providing the copy of the reservation information 700 (reservation information 700c) to the electronic key operation device 100.

The user terminal 1500 is a computer system connectable to the network 9, which is used by the user, and is implemented by, for example, a smartphone, a tablet computer, a notebook computer, or a wearable computer.

The user terminal 1500 can store and execute an application program. As the application program, a terminal program 502 is stored. The terminal program 502 implements (1) a function of accessing the server system 1100, (2) a function of performing a predetermined unlocking request to the electronic key operation device 100 according to an unlocking operation by a user and providing the reservation information 700t to unlock the electronic key operation device 100, and (3) a function of making a communication connection with the electronic key operation device 100 according to a locking operation by a user to perform a predetermined locking request, and providing the reservation information 700t to lock the electronic key operation device 100.

In FIG. 1, an arrow indicating a first direction X, a second direction Y, or a third direction Z indicates that a direction from a base end to a tip end of the arrow is a positive direction of a direction indicated by the arrow, and a direction from the tip end to the base end of the arrow is a negative direction of the direction indicated by the arrow. The first direction X is parallel to an insertion and removal direction of the electronic key accommodation case 300 with respect to the electronic key operation device 100. A positive direction of the first direction X is an insertion direction of the electronic key accommodation case 300. A negative direction of the first direction X is a removal direction of the electronic key accommodation case 300. In addition, the first direction X corresponds to a longitudinal direction of the housing 10 described later. The second direction Y is orthogonal to the first direction X and parallel to a thickness direction of the electronic key operation device 100. In addition, the second direction Y corresponds to a width direction of the housing 10 described later. The third direction Z is orthogonal to both the first direction X and the second direction Y. The third direction Z is parallel to a depth direction of the electronic key operation device 100. A positive direction of the third direction Z is a direction from the electronic key accommodation case 300 toward the electronic key operation device 100. A negative direction of the third direction Z is a direction from the electronic key operation device 100 toward the electronic key accommodation case 300. In addition, the third direction Z corresponds to a direction from a bottom surface 11 of the housing 10 described later toward the inside of the housing 10.

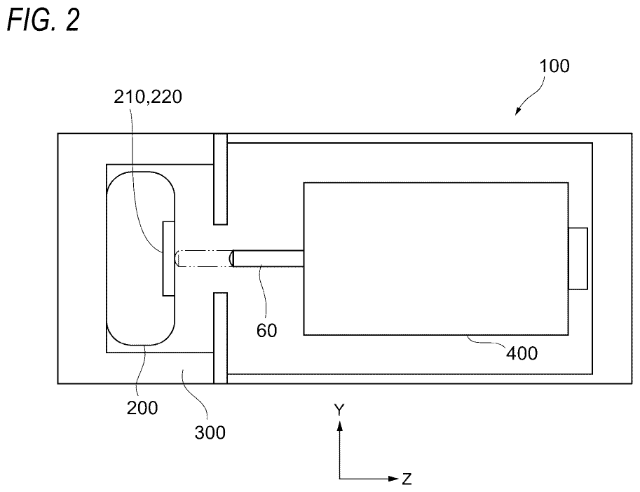

FIG. 2 conceptually shows an operation of the electronic key operation device 100 according to an embodiment. The electronic key operation device 100 includes an actuator 400 and a pressing member 60. The electronic key 200 is accommodated in the electronic key accommodation case 300, and the electronic key accommodation case 300 is mounted on the electronic key operation device 100 by a mounting portion (not shown). At this time, the electronic key 200 is positioned and held in the electronic key accommodation case 300 such that buttons 210 and 220 face the electronic key operation device 100.

The actuator 400 is controlled by a control unit (not shown) and serves as a driving unit that directly or indirectly applies power to the pressing member 60. The actuator 400 may be, for example, an electromagnetic solenoid, specifically, a push-type linear solenoid, and can push out the rod-shaped pressing member 60 by an electromagnetic force as a drive current is applied. When an instruction to unlock or lock the electronic key 200 is given to the electronic key operation device 100 via the network 9, the actuator 400 pushes out the pressing member 60 according to a control instruction, and a tip end of the pressing member 60 is to press down the buttons 210 and 220 of the electronic key 200. After the pressing member 60 presses the button 210 of the electronic key 200 and the power of the actuator 400 is stopped, the pressing member 60 can return to an original position by a return mechanism.

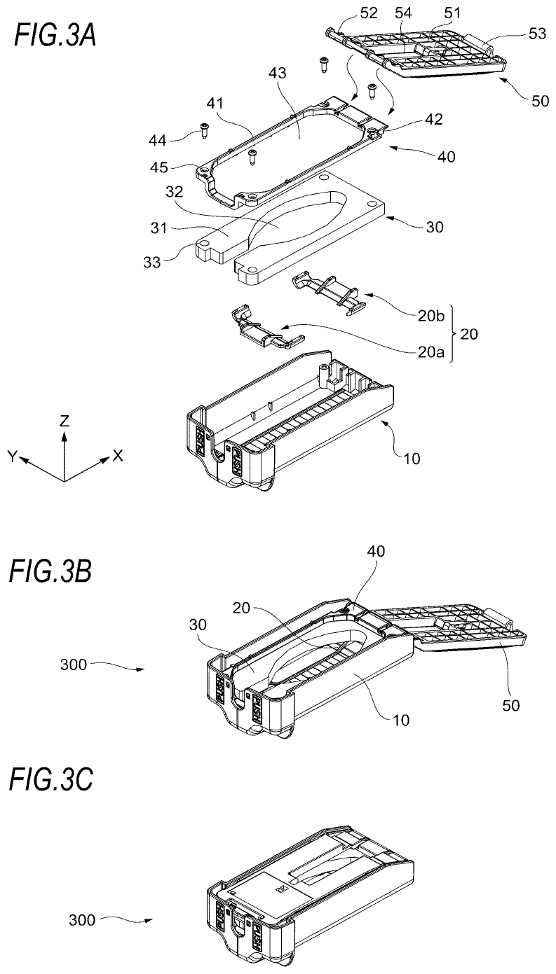

FIGS. 3A to 3C show schematic diagrams showing an outline of the electronic key accommodation case 300 according to the embodiment, where FIG. 3A is an exploded perspective view, FIG. 3B is a perspective view showing an assembly state in which the lid 50 is opened, and FIG. 3C is a perspective view showing an assembly state in which the lid 50 is closed. As shown in FIG. 3A, the electronic key accommodation case 300 according to the embodiment includes the housing 10, the position regulating unit 20, a key guide 30, a retainer plate 40, and the lid 50.

As shown in FIGS. 3A to 3C, the electronic key accommodation case 300 is assembled by attaching the position regulating unit 20 to the inside of the housing 10 and positioning the position regulating unit 20 within the housing 10, disposing the key guide 30 and the retainer plate 40 in this order on the position regulating unit 20, and closing the lid 50. Although not shown in FIGS. 3A to 3C, by fitting the electronic key 200 into the key guide 30, the electronic key 200 is accommodated inside the electronic key accommodation case 300. In the example shown in FIGS. 3A to 3C, the retainer plate 40 and the lid 50 are used to cover an upper surface, whereas the retainer plate 40 and the lid 50 may be omitted, and the upper surface of the electronic key accommodation case 300 may be covered with a member such as a cover or a partition wall provided in the electronic key operation device 100.

The housing 10 constitutes an outer shape of the electronic key accommodation case 300, and accommodates the position regulating unit 20, the key guide 30, and the electronic key 200 therein. A material constituting the housing 10 is not limited, and a resin material or metal material known in the related art can be used. For moldability and weight reduction, the resin material is preferably used. Detailed description of a structure and functions of the housing 10 will be described later.

The position regulating unit 20 is a member that is attached to the inside of the housing 10 to position the electronic key 200 in the electronic key accommodation case 300 and further regulates a movement of the positioned electronic key 200. In the example shown in FIG. 3A, the position regulating unit 20 includes two partial regulating units 20a and 20b. Inside the housing 10, the partial regulating units 20a and 20b are positioned on any one of a positioning unit 14 among a plurality of positioning units 14 provided on a surface facing an inner surface of a lid portion 51 when the lid 50 is closed, and are attached to the housing 10.

Although details of the positioning unit 14 will be described later, the positioning unit 14 determines the positions of the partial regulating units 20a and 20b with respect to the housing 10. That is, a worker who assembles the electronic key accommodation case 300 (hereinafter, simply referred to as a “worker”) positions each of the partial regulating units 20a and 20b on any one of the plurality of positioning units 14 in accordance with a size of the electronic key 200 accommodated in the electronic key accommodation case 300, and attaches the partial regulating units 20a and 20b to the housing 10. The electronic key 200 accommodated in the electronic key accommodation case 300 is held in the housing 10 by being positioned in the housing 10 by being brought into contact with a part of each of the partial regulating units 20a and 20b and the movement of the electronic key 200 in a height direction and a horizontal direction intersecting the height direction being regulated. Detailed description of a structure and functions of the position regulating unit 20 will be described later. In the embodiment, the plurality of positioning units 14 include a collection or a continuous structure of a large number of positioning units 14. In this case, the user can attach the position regulating unit 20 to any position on the positioning unit 14. In this case, a fixing unit for fixing the position regulating unit 20 to the positioning unit 14 may be provided.

The key guide 30 is a member which is disposed on the position regulating unit 20 in the housing 10 and into which the electronic key 200 is fitted. As shown in FIG. 3A, the key guide 30 includes a frame 31, a key fitting portion 32, and fixing portions 33. Although a material constituting the key guide 30 is not limited, it is preferable to use a resin material in order to easily form the key fitting portion 32 corresponding to the outer shape of the electronic key 200. The key guide 30 only needs to have a strength capable of auxiliary regulating the movement of the electronic key 200 in the horizontal direction, and a porous body or a hard sponge body formed of a resin material may be used for weight reduction.

The frame 31 is a substantially plate-shaped member which is formed to have an outer shape along an inner periphery of the housing 10 and has the key fitting portion 32 cut out. The fixing portions 33 are provided at four corners of the frame 31, and are fixed to the housing 10 by the fixing portions 33. In FIGS. 3A to 3C, a plate-shaped member having a uniform thickness is shown as the frame 31, and the shape is not limited. A curved surface or a region in which the thickness changes may be provided. The key fitting portion 32 is a region cut out from a front surface side to a back surface side within a plane of the frame 31, and is formed in a shape corresponding to the outer shape of the electronic key 200 to be accommodated. A formation position of the key fitting portion 32 is appropriately set at a position where the buttons 210 and 220 of the electronic key 200 are appropriately pressed by pressing members 61 and 62, which will be described later. The fixing portions 33 are through holes formed at four corners of the frame 31, and fixing members 44 to be described later are inserted into the fixing portions 33 and fastened to the housing 10. FIGS. 3A to 3C show examples in which the fixing portions 33 are provided at four corners, and the number and the position are not limited.

The retainer plate 40 is a member that is disposed on the key guide 30 in the housing 10, and prevents the position regulating unit 20 and the key guide 30 from falling off by sandwiching the position regulating unit 20 and the key guide 30 between the housing 10. As shown in FIG. 3A, the retainer plate 40 includes a retaining frame 41, a shaft fixing portion 42, an opening 43, the fixing members 44, and fixing portions 45. A material constituting the retainer plate 40 is not limited, and any known resin material or metal material may be used as long as the material has enough rigidity to prevent the position regulating unit 20 and the key guide 30 from falling off and being deviated.

The retaining frame 41 is a frame-shaped member formed along the inner periphery of the housing 10. As shown in FIG. 3A, the fixing portions 45, which are through holes, are formed at four corners of the retaining frame 41, and the shaft fixing portion 42 is provided on one side. The shaft fixing portion 42 is a portion that pivotally supports a rotary shaft 52 of the lid 50 described later. In the example shown in FIG. 3A, the shaft fixing portion 42 is an arc-shaped notch formed on a surface of the retaining frame 41 facing the key guide 30, and has a structure in which the rotary shaft 52 is pivotally supported by being sandwiched between the shaft fixing portion 42 and the key guide 30. The opening 43 is an opening formed in a center of the retaining frame 41, and is formed in a region larger than the key fitting portion 32 of the key guide 30 to such an extent that the retaining frame 41 does not interfere with the electronic key 200. The fixing members 44 are screw members inserted into the fixing portions 45 and the fixing portions 33, and fix the key guide 30 and the retainer plate 40 to the housing 10 by being fastened to screw holes provided in the housing 10. Here, the screw members are exemplified as the fixing member 44, and the structure is not limited as long as the key guide 30 and the retainer plate 40 can be fixed to the housing 10.

The lid 50 is a member that covers an upper portion of the housing 10 and is brought into contact with an upper surface of the accommodated electronic key 200 to prevent the electronic key 200 from falling off. As shown in FIG. 3A, the lid 50 includes the lid portion 51, the rotary shaft 52, a locking portion 53, and an opening 54. A material constituting the lid 50 is not limited, and any known resin material or metal material may be used as long as the material has enough rigidity to prevent the electronic key 200 from falling off and being deviated.

The lid portion 51 is a substantially plate-shaped portion that covers the upper surface of the housing 10 and regulates an upward movement of the electronic key 200. The rotary shaft 52 is provided on one side of the lid portion 51, and the locking portion 53 is provided on the other side. The opening 54 is formed in the lid portion 51, and even in a state in which the lid portion 51 is closed, the buttons 210 and 220 of the accommodated electronic key 200 are exposed on the upper surface, and the buttons 210 and 220 can be pressed down by the pressing members 61 and 62 described later. Although FIGS. 3A to 3C show examples in which the lid portion 51 is accommodated inside the housing 10, the lid portion 51 may have a size that covers the entire housing 10. In FIGS. 3A to 3C, in order to reduce the weight and secure the rigidity, the lid portion 51 having a cross-shaped honeycomb structure is exemplified, and the structure is not limited as long as the falling off and the positional deviation of the electronic key 200 can be prevented.

The rotary shaft 52 is a substantially columnar portion formed on one side of the lid portion 51, and is pivotally supported by the shaft fixing portion 42 of the retainer plate 40. Although FIG. 3A shows an example in which the rotary shaft 52 is integrally formed of a material same as that of the lid portion 51, only the rotary shaft 52 may be formed of a separate member such as metal in order to secure strength. The locking portion 53 is a portion formed on the other side of the lid portion 51 located on an opposite side from the rotary shaft 52, and is formed at a position and in a shape corresponding to a locking structure provided on the housing 10. In FIG. 3A, a latch structure formed of an elastic body is used as the locking portion 53, and the shape and the structure are not limited. Although an example in which the locking portion 53 is integrally formed of a material same as that of the lid portion 51 is shown, the locking portion 53 may be formed of a different material or may be formed separately from the lid portion 51. The opening 54 is an opening formed in the lid portion 51, and is formed at a position corresponding to the buttons 210 and 220 of the electronic key 200.

As shown in FIG. 3B, in an assembly state, the position regulating unit 20 is positioned and attached to the inside of the housing 10, the key guide 30 and the retainer plate 40 are disposed on the position regulating unit 20, and the key guide 30 and the retainer plate 40 are fixed to the housing 10 by the fixing members 44. At this time, the rotary shaft 52 of the lid 50 is sandwiched between the frame 31 and the shaft fixing portion 42 and is pivotably supported. Accordingly, the lid 50 pivots around the rotary shaft 52, and can be changed between an assembly state in which the lid 50 is opened as shown in FIG. 3B and an assembly state in which the lid 50 is closed as shown in FIG. 3C.

In the assembly state shown in FIG. 3B in which the lid 50 is opened, the key fitting portion 32 of the key guide 30 is exposed upward, and the electronic key 200 can be fitted and removed. In the assembly state shown in FIG. 3C in which the lid 50 is closed, the locking portion 53 of the lid 50 is engaged with the locking structure of the housing 10, and the lid portion 51 is in contact with the upper surface of the accommodated electronic key 200. Accordingly, the electronic key 200 is sandwiched between the lid portion 51 and the position regulating unit 20, and the movement of the electronic key 200 is regulated. In a state in which the lid 50 is closed, the buttons 210 and 220 of the electronic key 200 are exposed from the opening 54 formed in the lid portion 51, and can be pressed down by the pressing members 61 and 62 from the outside.

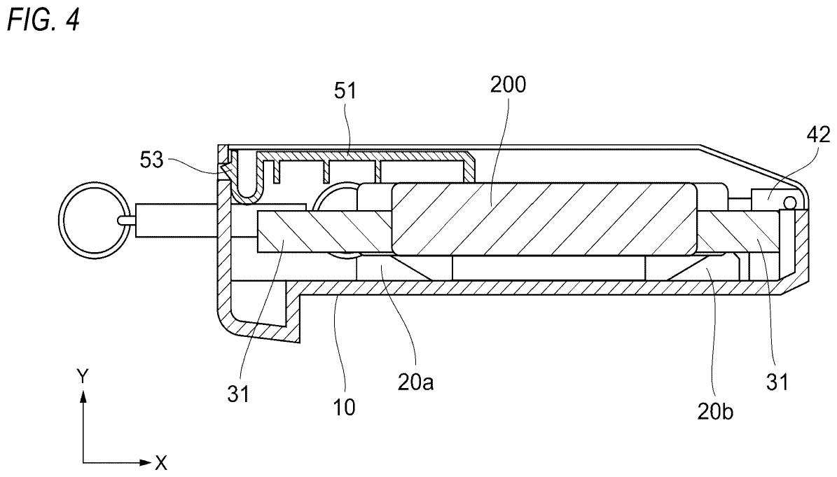

FIG. 4 is a schematic cross-sectional view of the electronic key 200 along a longitudinal direction, showing the outline of the electronic key accommodation case 300. As shown in FIG. 4, the electronic key 200 is fitted into the key fitting portion 32 provided in the frame 31 of the key guide 30, and a movement in the horizontal direction (a left-right direction in FIG. 4 and a direction perpendicular to a paper surface) is regulated. The partial regulating units 20a and 20b of the position regulating unit 20 are in contact with a lower surface side of the electronic key 200, and the lid portion 51 of the lid 50 is in contact with an upper surface side of the electronic key 200. Therefore, the electronic key 200 is held between the position regulating unit 20 and the lid 50, and a movement in an up-down direction is regulated. As shown in FIG. 4, a height at which the lid portion 51 of the lid 50 is in contact with the electronic key 200 is determined by a thickness of the lid portion 51. By changing the position of the position regulating unit 20 in the positioning unit 14, the position at which the position regulating unit 20 is in contact with the electronic key 200 can be changed. Accordingly, by determining the position of the position regulating unit 20 (the partial regulating units 20a and 20b) with respect to the housing 10 in the positioning unit 14 according to various forms of the electronic key 200, the movement of the electronic key 200 in the housing 10 can be appropriately regulated.

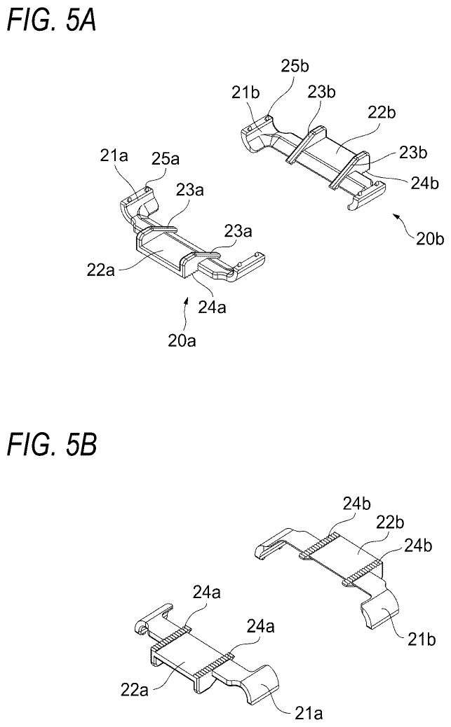

FIGS. 5A and 5B show schematic diagrams showing a structure of the position regulating unit 20 according to the embodiment, where FIG. 5A is an upper perspective view, and FIG. 5B is a lower perspective view. As shown in FIGS. 5A and 5B, the position regulating unit 20 is implemented to be separated into two partial regulating units 20a and 20b, and includes extension portions 21a and 21b, holding units 22a and 22b, tapered portions 23a and 23b, engaging portions 24a and 24b, and protrusion portions 25a and 25b. The material constituting the position regulating unit 20 is not limited, and a resin material is preferably used from the viewpoint of moldability and weight reduction. In addition, as will be described later, in order to reliably hold the electronic key 200 and prevent the electronic key 200 from swinging or being deviated when the buttons 210 and 220 of the accommodated electronic key 200 are pressed down, it is preferable that the position regulating unit 20 has a hardness to such an extent that the position regulating unit 20 is not deformed even when a force due to the pressing down is applied.

The partial regulating units 20a and 20b constitute the position regulating unit 20 in the embodiment, and are members that are selectively attached to any of the plurality of positioning units 14 provided in the housing 10 to be described later, and are in contact with the lower surface side of the electronic key 200. In the example shown in FIGS. 5A and 5B, the partial regulating units 20a and 20b are each formed in a bilaterally symmetrical shape. The partial regulating unit 20a and the partial regulating unit 20b have the same shape, and are disposed so that the tapered portions 23a and 23b face each other. Although FIGS. 5A and 5B show examples in which the partial regulating units 20a and 20b are bilaterally symmetrical and have the same shape, the partial regulating units 20a and 20b may be bilaterally asymmetrical and may have different shapes. However, by making the partial regulating units 20a and 20b have the same shape in a bilaterally symmetrical shape, the number of components can be reduced by commonality of the components, and the partial regulating units 20a and 20b can function correctly even when the arrangement of the partial regulating units 20a and 20b is switched, thereby preventing erroneous assembly.

The extension portions 21a and 21b are portions formed to extend in a left-right direction of the partial regulating units 20a and 20b to a side surface 13 of the housing 10. In the example shown in FIGS. 5A and 5B, the extension portions 21a and 21b extend along the bottom surface 11 of the housing 10, and are formed in a lower surface shape along a corner 12 and the side surface 13 of the housing 10. In addition, the extension portions 21a and 21b are formed to have a height to be in contact with the key guide 30, and a plurality of protrusion portions 25a and 25b are formed on upper surfaces of the extension portions 21a and 21b to protrude upward. The extension portions 21a and 21b that reach the side surface 13 of the housing 10 further have portions that extend in the longitudinal direction (the horizontal direction in FIG. 4) along the side surface 13.

The holding units 22a and 22b are portions that are in contact with and hold the electronic key 200. The extension portions 21a and 21b extend from both sides of the holding units 22a and 22b, the tapered portions 23a and 23b are provided on an upper surface side of the holding units 22a and 22b, and the engaging portions 24a and 24b are provided on a back surface side of the holding units 22a and 22b. FIGS. 5A and 5B show examples in which the holding units 22a and 22b are provided with the tapered portions 23a and 23b, and the tapered portions 23a and 23b are in contact with the lower surface side of the electronic key 200. Portions other than the tapered portions 23a and 23b may be in contact with the electronic key 200.

The tapered portions 23a and 23b are portions that are provided on the front surface side of the holding units 22a and 22b and have surfaces inclined with respect to the bottom surface 11 of the housing 10. In the example shown in FIGS. 5A and 5B, the tapered portions 23a and 23b are formed at two positions on each of the left and right sides, and the lower surface side of the electronic key 200 and the tapered portions 23a and 23b are in contact with each other at four positions in total. Accordingly, it is possible to stably support the lower surface side of the electronic key 200 at four points and to regulate the movement of the electronic key 200 not only in the longitudinal direction but also in the width direction. Here, an example in which the tapered portions 23a and 23b are in contact with the electronic key 200 at a total of four positions is shown, whereas the electronic key 200 can be stably supported by the contact at three points at least.

The tapered portions 23a and 23b are formed at a constant inclination angle with respect to the bottom surface 11 of the housing 10, and the positions where the tapered portions are in contact with the electronic key 200 change depending on the size and the lower surface shape of the electronic key 200. Therefore, by adjusting a distance between the partial regulating units 20a and 20b in the longitudinal direction, it is possible to appropriately set the position at which the lower surface side of the electronic key 200 and the tapered portions 23a and 23b are in contact with each other. At this time, since heights of the tapered portions 23a and 23b are different depending on a contact position, a height of the electronic key 200 can also be adjusted. As an example, when the inclination angle of the tapered portions 23a and 23b is set to θ, and tan θ=½, half of the change in the contact position in the longitudinal direction becomes the change in the height direction. By keeping the inclination angle θ of the tapered portions 23a and 23b constant in this way, for example, by moving the distance between the partial regulating units 20a and 20b by 1.0 mm in the longitudinal direction, the contact position between the tapered portions with the electronic key 200 in the height direction can be changed by 0.5 mm, allowing highly accurate positioning with a simple process.

In addition, since the tapered portions 23a and 23b are inclined, a drag force that the electronic key 200 receives from the tapered portions 23a and 23b when the electronic key 200 is brought into contact therewith has components in two directions in the height direction and the longitudinal direction. Therefore, the movement of the electronic key 200 in the height direction and the longitudinal direction (the horizontal direction) intersecting with the height direction with respect to the housing 10 is regulated by the position regulating unit 20. In the example shown in FIGS. 5A and 5B, the tapered portions 23a and 23b are formed with a constant inclination angle, and may be formed with curved surfaces or multi-step inclinations.

The distance between the tapered portions 23a and 23b in the width direction is preferably wider than a button arrangement of the electronic key 200. Similarly, it is also preferable that the distance between the tapered portions 23a and 23b in the longitudinal direction is such that the contact position between the tapered portions with the electronic key 200 is outside the button arrangement in a plan view. The distance between the tapered portions 23a and 23b determines the position in contact with the lower surface side of the electronic key 200, and determines the position at which the movement of the electronic key 200 is regulated. Therefore, since the lower surface side of the electronic key 200 is supported by the tapered portions 23a and 23b at a position outside the arrangement of the buttons 210 and 220, even if a pressing force in the direction of the bottom surface 11 is applied to the electronic key 200 when the buttons 210 and 220 are pressed down, it is possible to prevent swinging or positional deviation of the electronic key 200.

The engaging portions 24a and 24b are portions that are provided on a back surface side of the holding units 22a and 22b, are provided to face the positioning units 14 of the housing 10, and are formed in a shape to engage with the positioning units 14. In the example shown in FIGS. 5A and 5B, the engaging portions 24a and 24b have a rack gear shape in which a plurality of unevenness are linearly arranged, and are provided in parallel along the longitudinal direction. The engaging portions 24a and 24b are located on a back side of the tapered portions 23a and 23b. Accordingly, when the electronic key 200 is brought into contact with the tapered portions 23a and 23b, a force acting on the tapered portions 23a and 23b in the direction of the bottom surface 11 is directly transmitted to the engaging portions 24a and 24b, and the engaging portions 24a and 24b are reliably engaged with the positioning units 14.

The protrusion portions 25a and 25b are portions provided to protrude upward from the upper surfaces of the extension portions 21a and 21b. When the electronic key accommodation case 300 is assembled, the upper surfaces of the extension portions 21a and 21b are in contact with the lower surface of the key guide 30. At this time, when the key guide 30 is made of a hard sponge or the like, the protrusion portions 25a and 25b bite into the lower surface of the key guide 30, and thus it is possible to prevent the positional deviation of the partial regulating units 20a and 20b. In the example shown in FIGS. 5A and 5B, as an example of the protrusion portions 25a and 25b, a shape having a triangular cross section in the width direction and a top side in the longitudinal direction is shown, and the shape is not limited. However, in order to improve an effect of preventing the positional displacement by the protrusion portions 25a and 25b biting into the key guide 30, it is preferable to use the protrusion portions 25a and 25b having a shape in which a predetermined plane is exposed in an extending direction.

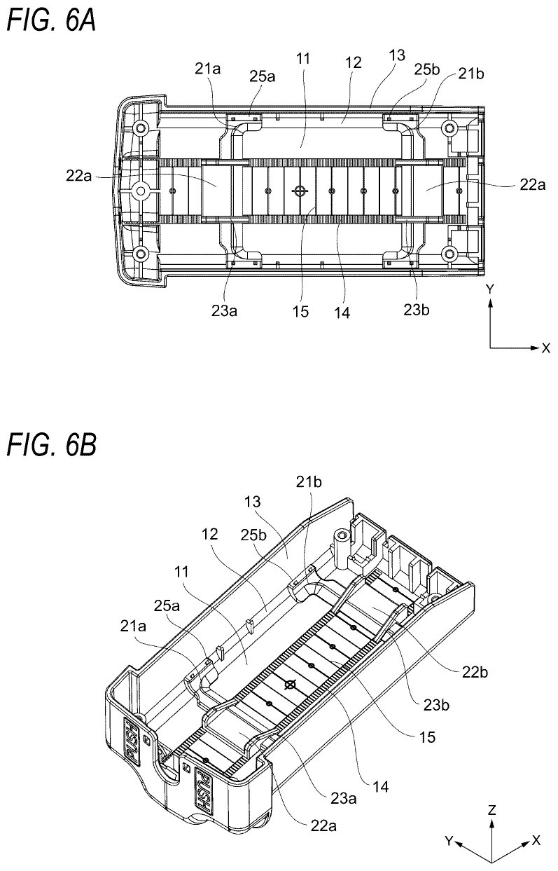

FIGS. 6A and 6B show schematic diagrams showing an arrangement of the position regulating unit 20 inside the housing 10, where FIG. 6A is a top view, and FIG. 6B is a perspective view. As shown in FIGS. 6A and 6B, the housing 10 includes the bottom surface 11, the corner 12, the side surface 13, the positioning units 14, and an indicator unit 15. The housing 10 is formed into a box shape with an open top surface. The material constituting the housing 10 is not limited, and a resin material is preferably used from the viewpoint of moldability and weight reduction. The partial regulating units 20a and 20b constituting the position regulating unit 20 are positioned and attached to the bottom surface 11 of the housing 10.

The bottom surface 11 is a surface constituting the bottom of the housing 10, the side surface 13 is erected on an outer peripheral portion, and the corner 12 is formed at a portion where the bottom surface 11 and the side surface 13 intersect. The plurality of positioning units 14 and the indicator unit 15 are provided on a front surface side of the bottom surface 11. The corner 12 is a corner where the bottom surface 11 and the side surface 13 intersect. Although FIGS. 6A and 6B show examples in which the corner 12 is formed to have a curved surface having an arc-shaped cross section, the corner 12 may be formed such that the bottom surface 11 and the side surface 13 intersect at a substantially right angle. The side surface 13 is a wall-shaped portion provided to erect upward from an outer periphery of the bottom surface 11.

The positioning units 14 are portions that are provided on the bottom surface 11 of the housing 10 and with which the engaging portions 24a and 24b of the position regulating unit 20 are engaged. In the example shown in FIGS. 6A and 6B, the positioning units 14 have a rack gear shape in which a plurality of unevenness are linearly arranged, and are arranged in two parallel straight lines along the longitudinal direction of the electronic key 200. In addition, the plurality of unevenness as the positioning units 14 have a constant height and pitch, and correspond to the shapes of the engaging portions 24a and 24b formed on a back surface of the position regulating unit 20. By disposing the position regulating unit 20 at any position on the positioning units 14, the positioning units 14 and the engaging portions 24a and 24b are engaged with each other, and a sliding movement in the longitudinal direction is regulated and the position is determined. In the example shown in FIGS. 6A and 6B, although an example in which two positioning units 14 are provided along the longitudinal direction is shown, three or more positioning units 14 may be provided, and one positioning unit 14 may be provided in the center.

The indicator unit 15 is provided on the bottom surface 11 and is a mark for distinguishing the plurality of positioning units 14. In the example shown in FIGS. 6A and 6B, the indicator unit 15 is a plurality of straight lines extending in the width direction for each unevenness shape of a certain number of the positioning units 14, and functions as a scale indicating a position of each of five convex shapes as an example. In addition, as shown in FIGS. 6A and 6B, at least one indicator unit 15 is provided at a position not overlapping the position regulating unit 20, and it is preferable that several indicator units 15 can be visually recognized even in a state in which the position regulating unit 20 is selectively attached to the positioning unit 14. Since the indicator unit 15 can be visually recognized in a state in which the position regulating unit 20 is disposed, it is possible to easily visually check at which position the position regulating unit 20 is disposed in the longitudinal direction.

In the example shown in FIGS. 6A and 6B, the positioning units 14 are provided at positions overlapping the holding units 22a and 22b in a plan view. Accordingly, when the electronic key 200 is accommodated on the position regulating unit 20 and the tapered portions 23a and 23b are in contact with the lower surface of the electronic key 200, the positioning units 14 and the engaging portions 24a and 24b reliably engage with each other by a force applied to the tapered portions 23a and 23b. In addition, it is more preferable that the tapered portions 23a and 23b, the engaging portions 24a and 24b, and the positioning units 14 overlap in a plan view.

The partial regulating units 20a and 20b constituting the position regulating unit 20 are independently attached to any of the plurality of positioning units 14. Accordingly, when the positions at which the partial regulating units 20a and 20b are disposed are set and the engaging portions 24a and 24b are engaged with the positioning units 14, the positions of the partial regulating units 20a and 20b in the longitudinal direction and the distance therebetween are determined. At this time, when a temporary member such as an adhesive tape is attached to the back surface side of the holding units 22a and 22b, it is possible to prevent the partial regulating units 20a and 20b from falling off and being deviated in an assembly process.

In the example shown in FIGS. 6A and 6B, for example, for each piece of information identifying a type of the electronic key 200 such as a vehicle type and a model number, it is determined at which position in the positioning units 14 the partial regulating units 20a and 20b are to be disposed. Accordingly, the worker who assembles the electronic key accommodation case 300 can accurately set an in-plane position and the height of the electronic key 200 in the housing 10 only by checking the type of the electronic key 200 and the arrangement position corresponding thereto and disposing the partial regulating units 20a and 20b on the positioning units 14.

As an example shown in FIGS. 6A and 6B, the central indicator unit 15 is provided with a large circle and a cross shape, and other indicator units 15 are formed at every five convex shapes, and the every other indicator unit 15 is provided with a small circle. Therefore, depending on the type of the electronic key 200, it is possible to easily perform work such as disposing the partial regulating unit 20a in a 16-th convex shape from the center and disposing the partial regulating unit 20b in a 30-th convex shape on the opposite side from the center. In addition, by visually checking the indicator unit 15 and the partial regulating units 20a and 20b, it is possible to easily check whether the partial regulating units 20a and 20b are disposed at correct positions.

When the pitch of the unevenness shape of the positioning unit 14 is constant and the inclination angle of the tapered portions 23a and 23b is constant, an amount of displacement of the electronic key 200 in the height direction can be easily grasped when the partial regulating units 20a and 20b are moved by one convex shape. As a specific example, when the unevenness shape of the positioning unit 14 is formed at a pitch of 1 mm and the inclination angle θ of the tapered portions 23a and 23b is tan θ=½, when the partial regulating units 20a and 20b are moved by one convex shape, the height of the electronic key 200 is displaced by 0.5 mm. Accordingly, the height of the electronic key 200 can be precisely and easily adjusted only by differentiating the arrangement of the partial regulating units 20a and 20b in the longitudinal direction.

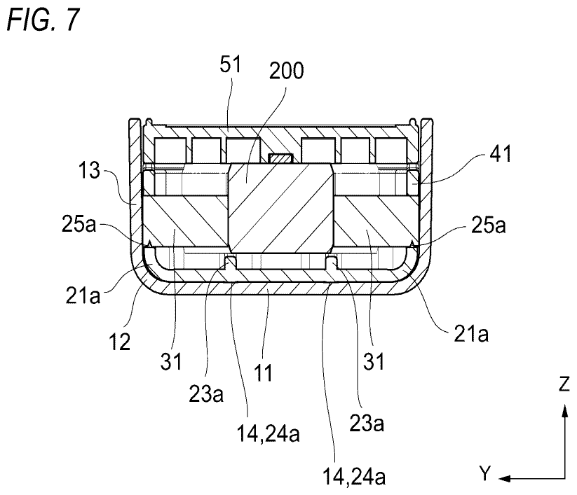

FIG. 7 is a schematic cross-sectional view of the electronic key 200 along a transverse direction, showing the outline of the electronic key accommodation case 300. Although FIG. 7 shows only the cross-sectional view at the position of the partial regulating unit 20a, the partial regulating unit 20b also has the same positional relationship. As shown in FIG. 7, in the partial regulating unit 20a disposed on the bottom surface 11, the engaging portion 24a is engaged with the positioning unit 14. The extension portions 21a extend in the width direction along the bottom surface 11 and are in contact with the corner 12 and the side surface 13. The upper surfaces of the extension portions 21a are in contact with the frame 31 of the key guide 30. The tapered portions 23a are in contact with the lower surface side of the electronic key 200 to regulate the movement of the electronic key 200 in the width direction, the longitudinal direction, and the height direction.

Since the electronic key 200 is fitted into the key fitting portion 32 of the key guide 30 and is surrounded by the frame 31, the movement in the width direction and the longitudinal direction is also regulated by the key guide 30. In addition, the lid portion 51 of the lid 50 is in contact with the upper surface side of the electronic key 200, and the electronic key 200 is sandwiched between the lid portion 51 and the tapered portions 23a to regulate the movement in the up-down direction. The retaining frame 41 of the retainer plate 40 is sandwiched between the lid portion 51 and the frame 31, and accordingly, the retaining frame 41, the frame 31, and the extension portions 21a are sandwiched between the lid portion 51 and the corner 12.

As described above, the extension portions 21a reach the side surface 13 and further have the portions that extend in the longitudinal direction along the side surface 13. Accordingly, the bottom surface 11, the corner 12, the side surface 13, and the frame 31 are in surface contact with the extension portion 21a of the partial regulating unit 20a, and the engaging portion 24a and the positioning unit 14 are engaged with each other, thereby preventing the positional deviation and the falling off. In addition, the protrusion portion 25a formed on the upper surface of the extension portion 21a bites into the frame 31 formed of the hard sponge, and the movement of the partial regulating unit 20a in the horizontal direction is more firmly regulated, thereby preventing the positional deviation and the falling off.

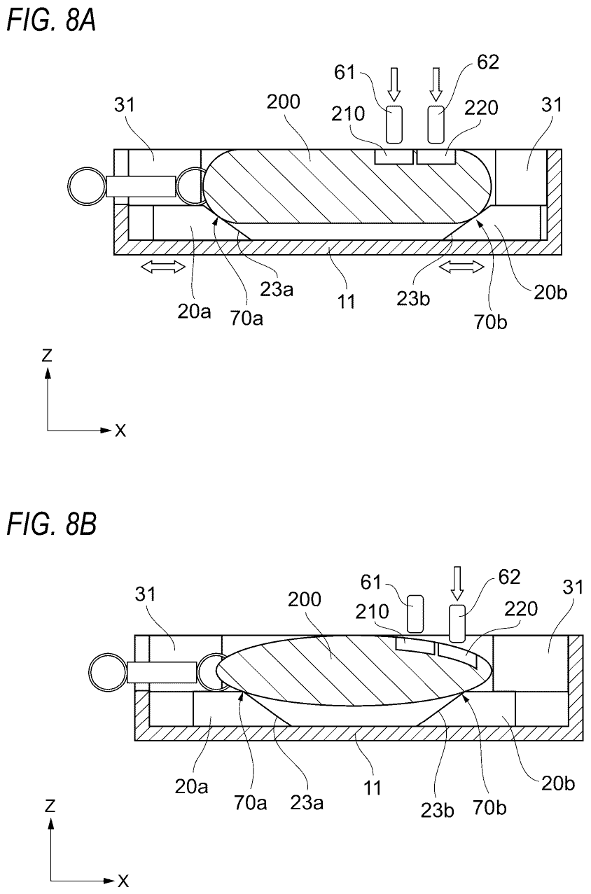

FIGS. 8A and 8B show schematic diagrams showing holding of the electronic keys 200 having different forms by the position regulating unit 20, where FIG. 8A shows a case in which a cross section is close to a rectangle and has corners, and FIG. 8B shows a case in which the cross section is close to an ellipse or an oval and has no corner. In FIGS. 8A and 8B, the retainer plate 40 and the lid 50 are not shown for the sake of simplicity. As shown FIGS. 8A and 8B, even if the forms of the electronic key 200 are different, contact portions 70a and 70b are in contact with the lower surface side of the electronic key 200 by appropriately selecting positions at which the partial regulating units 20a and 20b are attached. At this time, a highest position of the electronic key 200 is set to be substantially flush with the upper surface of the frame 31.

In the example shown in FIG. 8A, since the cross section of the electronic key 200 is close to a rectangle and has corners, the inclined surfaces of the tapered portions 23a and 23b serve as the contact portions 70a and 70b. In this case, since the contact portions 70a and 70b are within the inclined surfaces of the tapered portions 23a and 23b, a drag force that the electronic key 200 receives from the partial regulating units 20a and 20b is in a direction perpendicular to the inclined surfaces and has components in the height direction and the horizontal direction with respect to the bottom surface 11. Accordingly, the movement of the electronic key 200 in the height direction and the horizontal direction intersecting with the height direction with respect to the housing 10 is regulated by the position regulating unit 20.

In the example shown in FIG. 8B, since the cross section of the electronic key 200 is close to an ellipse or an oval and has no corner, uppermost portions of the tapered portions 23a and 23b are the contact portions 70a and 70b. In this case, since the lower surface side of the electronic key 200 is a curved surface, the drag force that the electronic key 200 receives from the partial regulating units 20a and 20b is in a direction perpendicular to the curved surface, and has components in the height direction and the horizontal direction with respect to the bottom surface 11. Accordingly, the movement of the electronic key 200 in the height direction and the horizontal direction intersecting with the height direction with respect to the housing 10 is regulated by the position regulating unit 20.

When a signal instructing a button operation is transmitted to the electronic key operation device 100, the pressing members 61 and 62 are driven by the actuator 400 or the like, and the buttons 210 and 220 of the electronic key 200 are pressed down from the outside of the electronic key accommodation case 300. At this time, since the partial regulating units 20a and 20b constituting the position regulating unit 20 are formed of a material and a structure having a predetermined hardness, the movement of the electronic key 200 in the height direction or the horizontal direction while being pressed down is prevented, and the buttons 210 and 220 can be reliably pressed down.

As described above, in the electronic key accommodation case 300 according to the embodiment, since the position regulating unit 20 is selectively attached to any one of the plurality of positioning units 14, the electronic key 200 can be positioned and held in the housing 10 by making the arrangement of the position regulating unit 20 correspond to the shape of the electronic key 200. Accordingly, it is possible to cope with various electronic keys 200 while securing reliability of the pressing operation on the electronic key 200.

### Second Embodiment

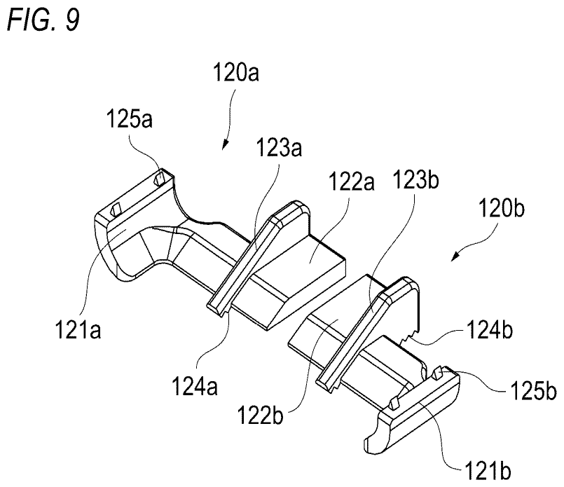

Next, a second embodiment according to the invention will be described with reference to FIG. 9. Description of contents overlapping with the first embodiment will be omitted. The embodiment is different from the first embodiment in that the position regulating unit 120 is further divided into left and right parts. FIG. 9 is a schematic perspective view showing a structure of the position regulating unit 20 according to the embodiment. As shown in FIG. 9, the position regulating unit 20 according to the embodiment is separated into two partial regulating units 120a and 120b, and includes extension portions 121a and 121b, holding units 122a and 122b, tapered portions 123a and 123b, engaging portions 124a and 124b, and protrusion portions 125a and 125b.

In the electronic key accommodation case 300 according to the embodiment, since the position regulating unit 120 includes the partial regulating units 120a and 120b which are divided into left and right parts, it is possible to hold the electronic key 200 by changing the attachment positions of the partial regulating units 120a and 120b in the longitudinal direction and appropriately regulating the movement in the longitudinal direction and the horizontal direction in response to the electronic key 200 having various outer shapes such as a parallel quadrilateral, a polygon, and a bilaterally asymmetrical shape.

### Third Embodiment

Next, a third embodiment according to the invention will be described. Description of contents overlapping with the first embodiment will be omitted. In the first embodiment, an example in which the two partial regulating units 20a and 20b are separately provided as the position regulating unit 20 is shown. However, in the embodiment, one of the position regulating units 20 may be formed integrally with the housing 10, and the other may be formed separately from the housing 10. In this case, although a degree of freedom and accuracy of positioning of the electronic key 200 are limited, the positioning unit 14 to which the position regulating unit 20 is attached can be easily selected, and an assembly process can be simplified.

### Fourth Embodiment

Next, a fourth embodiment according to the invention will be described. Description of contents overlapping with the first embodiment will be omitted. In the first embodiment, an example in which the positioning units 14 and the engaging portions 24a and 24b have a rack gear shape in which a plurality of unevenness are linearly arranged has been described, whereas shapes and structures of the positioning units 14 and the engaging portions 24a and 24b are not limited. For example, as the positioning unit 14, the positioning unit 14 may be formed by forming a recess or a through hole of a predetermined shape, and the engaging portions 24a and 24b may be pin-shaped that can be inserted into the recess or through hole. In this case, as the indicator unit 15, a lead line may be drawn from a periphery of the recess or the through hole, and a reference numeral for distinguishing the positioning units 14 may be drawn.

### Fifth Embodiment

Next, a fifth embodiment according to the invention will be described. Description of contents overlapping with the first embodiment will be omitted. In the first embodiment, although the configuration is shown in which the two tapered portions 23a and the two tapered portions 23b are provided in parallel to each other, and the tapered portions 23a and 23b are overlapped in the extending direction of the engaging portions 24a and 24b over the entire length, the arrangement of the tapered portions 23a and 23b is not limited to being parallel. As an example, the tapered portions 23a and 23b may be provided obliquely with respect to the longitudinal direction and the width direction of the electronic key 200 to extend radially from the electronic key 200. In this case, the movement of the electronic key 200 in the height direction and the width direction can be regulated more reliably by appropriately bringing the tapered portions 23a and 23b into contact with the lower surface side of the electronic keys 200 having various widths.

### Sixth Embodiment

Next, a sixth embodiment according to the invention will be described. Description of contents overlapping with the first embodiment will be omitted. In the first embodiment, an example is shown in which the positioning units 14 are provided on the bottom surface 11 of the housing 10. The position where the positioning units 14 are formed is not limited to the bottom surface 11. As an example, the positioning unit 14 may be provided on the corner 12 or the side surface 13 of the housing 10, and the engaging portions 24a and 24b may be provided at positions corresponding to the positioning units 14 among the extension portions 21a and 21b of the partial regulating units 20a and 20b.

The invention is not limited to the above-described embodiments, and various modifications can be made within the scope of the claims. Embodiments obtained by appropriately combining technical methods disclosed in different embodiments are also included in the technical scope of the invention.

According to the present specification, the following aspects are provided.

### Aspect 1

In Aspect 1, provided is an electronic key accommodation case that is detachably attached to an electronic key operation device configured to press a pressing button of an accommodated electronic key, the electronic key accommodation case includes: a housing configured to accommodate the electronic key; and a position regulating unit configured to regulate a position of the electronic key in the housing. The housing includes a plurality of positioning units that position the position regulating unit.

According to Aspect 1, compared to a case in which a shape of a storage space is changed according to a shape of the electronic key 200, it is possible to cope with various electronic keys 200 by simply selecting the positioning unit 14 and attaching the position regulating unit 20 thereto. In addition, as compared with a case in which the holding unit of the electronic key 200 is made of a flexible material such that a thickness of the holding unit of the electronic key 200 changes according to an outer shape of the electronic key 200, the position regulating unit 20 can be made of a material such as a resin that is less likely to be deformed, and therefore, it is possible to prevent positional deviation and swinging of the electronic key 200 and to secure reliability of a pressing operation.

### Aspect 2

In Aspect 2, the position regulating unit regulates a movement of the electronic key with respect to the housing in a height direction and a horizontal direction intersecting the height direction. According to Aspect 2, it is possible to appropriately set the position of the electronic key 200 in the height direction and the horizontal direction in the housing 10, accurately align the pressing members 61 and 62 and the buttons 210 and 220, and improve the reliability of the pressing operation.

### Aspect 3

In Aspect 3, the position regulating unit is divided into a plurality of partial regulating units, and each of the partial regulating units is independently positioned at any one of the plurality of positioning units. According to Aspect 3, it is possible to hold the electronic key 200 by changing the attachment positions of the partial regulating units 120a and 120b in the longitudinal direction and appropriately regulating the movement in the longitudinal direction and the width direction in response to the electronic key 200 having various outer shapes.

### Aspect 4

In Aspect 4, the position regulating unit includes a holding unit that is in contact with and holds the electronic key, and the holding unit and the positioning unit overlap each other in a plan view. According to Aspect 4, when the electronic key 200 is accommodated on the position regulating unit 20 and the tapered portions 23a and 23b are in contact with the lower surface of the electronic key 200, the positioning units 14 and the engaging portions 24a and 24b reliably engage with each other by a force applied to the tapered portions 23a and 23b.

### Aspect 5

In Aspect 5, the position regulating unit includes a tapered portion inclined with respect to a bottom surface of the housing. According to Aspect 5, depending on an inclination angle of the tapered portion 23a, a contact position between the tapered portions and the electronic key 200 in the height direction is set according to the position of the position regulating unit 20 in the horizontal direction, making it possible to easily adjust the position of the electronic key 200 in the height direction with high accuracy.

### Aspect 6

In Aspect 6, the positioning unit is unevenness provided on a bottom surface of the housing, has a rack gear shape in which a plurality of the unevenness are arranged in a line, and an engaging portion that engages with the unevenness is provided on a surface of the position regulating unit facing the bottom surface. According to Aspect 6, it is possible to finely set the position of the position regulating unit 20, and it is possible to hold the electronic key 200 of various forms by adjusting the position with high accuracy.

### Aspect 7

In Aspect 7, the position regulating unit includes an extension portion extending to a side surface of the housing, and the extension portion is in contact with the side surface. According to Aspect 7, the extension portion 21a is in surface contact with the side surface 13, and it is possible to prevent positional deviation or falling off of the position regulating unit 20.

### Aspect 8

In Aspect 8, a plurality of indicator units configured to distinguish the plurality of positioning units are provided in the housing, and in a state in which the position regulating unit is selectively attached to the positioning unit, at least one of the indicator units is provided at a position not overlapping the position regulating unit. According to Aspect 8, by visually checking the indicator unit 15 and the position regulating unit 20, positioning work of the position regulating unit 20 can be easily performed, and whether the position regulating unit 20 is disposed at a correct position can be easily checked.

### Aspect 9

In Aspect 9, an electronic key operation device that presses a pressing button of an accommodated electronic key includes: an electronic key accommodation case configured to accommodate the electronic key; and a pressing member configured to press the button of the electronic key accommodated in the electronic key accommodation case. The electronic key accommodation case includes a housing configured to accommodate the electronic key, a position regulating unit configured to regulate a position of the electronic key in the housing, and a plurality of positioning units configured to position the position regulating unit.

According to Aspect 9, compared to a case in which a shape of a storage space is changed according to a shape of the electronic key 200, it is possible to cope with various electronic keys 200 by simply selecting the positioning unit 14 and attaching the position regulating unit 20 thereto. In addition, as compared with a case in which the holding unit of the electronic key 200 is made of a flexible material such that a thickness of the holding unit of the electronic key 200 changes according to an outer shape of the electronic key 200, the position regulating unit 20 can be made of a material such as a resin that is less likely to be deformed, and therefore, it is possible to prevent positional deviation and swinging of the electronic key 200 and to secure reliability of a pressing operation.

### REFERENCE SIGNS LIST

100: electronic key operation device
200: electronic key
300: electronic key accommodation case
400: actuator
10: housing
20: position regulating unit
30: key guide
40: retainer plate
50: lid
11: bottom surface
12: corner
13: side surface
14: positioning unit
15: indicator unit
20a, 20b, 120a, 120b: partial regulating unit
21a, 21b, 121a, 121b: extension portion
22a, 22b, 122a, 122b: holding unit
23a, 23b, 123a, 123b: tapered portion
24a, 24b, 124a, 124b: engaging portion
25a, 25b, 125a, 125b: protrusion portion
31: frame
32: key fitting portion
33, 45: fixing portion
41: retaining frame
42: shaft fixing portion
43, 54: opening
44: fixing member
51: lid portion
52: rotary shaft
53: locking portion
60, 61, 62: pressing member
70a, 70b: contact portion
210, 220: button

1. An electronic key accommodation case that is detachably attached to an electronic key operation device configured to press a pressing button of an accommodated electronic key, the electronic key accommodation case comprising:
a housing configured to accommodate the electronic key; and
a position regulating unit configured to regulate a position of the electronic key in the housing, wherein
the housing includes a plurality of positioning units that position the position regulating unit.

2. The electronic key accommodation case according to claim 1, wherein
the position regulating unit regulates a movement of the electronic key with respect to the housing in a height direction and a horizontal direction intersecting the height direction.

3. The electronic key accommodation case according to claim 1, wherein
the position regulating unit is divided into a plurality of partial regulating units, and each of the partial regulating units is independently positioned at any one of the plurality of positioning units.

4. The electronic key accommodation case according to claim 1, wherein
the position regulating unit includes a holding unit that is in contact with and holds the electronic key, and the holding unit and the positioning unit overlap each other in a plan view.

5. The electronic key accommodation case according to claim 1, wherein
the position regulating unit includes a tapered portion inclined with respect to a bottom surface of the housing.

6. The electronic key accommodation case according to claim 1, wherein
the positioning unit is unevenness provided on a bottom surface of the housing, has a rack gear shape in which a plurality of the unevenness are arranged in a line, and an engaging portion that engages with the unevenness is provided on a surface of the position regulating unit facing the bottom surface.

7. The electronic key accommodation case according to claim 1, wherein
the position regulating unit includes an extension portion extending to a side surface of the housing, and the extension portion is in contact with the side surface.

8. The electronic key accommodation case according to claim 1, wherein
a plurality of indicator units configured to distinguish the plurality of positioning units are provided in the housing, and
in a state in which the position regulating unit is selectively attached to the positioning unit, at least one of the indicator units is provided at a position not overlapping the position regulating unit.

9. An electronic key operation device that presses a pressing button of an accommodated electronic key, comprising:
an electronic key accommodation case configured to accommodate the electronic key; and
a pressing member configured to press the button of the electronic key accommodated in the electronic key accommodation case, wherein
the electronic key accommodation case includes a housing configured to accommodate the electronic key, a position regulating unit configured to regulate a position of the electronic key in the housing, and a plurality of positioning units configured to position the position regulating unit.
